(19) United States
(12) Patent Application Publication
(10) Pub. No.: US 2026/0323959 A1
(43) Pub. Date: Oct. 15, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Ji Sung PARK, Icheon-si Gyeonggi-do (KR)

(73) Assignee: SK hynix Inc., Icheon-si Gyeonggi-do (KR)

(21) Appl. No.: 19/321,888

(22) Filed: Sep. 8, 2025

(30) Foreign Application Priority Data
Apr. 9, 2025 (KR) 10-2025-0046024

(51) Int. Cl. H10B 80/00; H10D 80/30; H10W 90/00; H10W 72/90; H10W 90/26

(52) U.S. Cl. CPC H10B 80/00; H10D 80/30; H10W 90/00; H10W 72/942; H10W 90/26; H10W 90/792

(57) ABSTRACT

A semiconductor device includes a first structure, a first bonding structure positioned on the first structure, and including a first bonding via having a first central axis and a first bonding pad having a second central axis aligned with the first central axis, a second bonding structure positioned on the first bonding structure, and including a second bonding via having a third central axis misaligned with the first central axis and a second bonding pad having a fourth central axis aligned with the first central axis, and a second structure positioned on the second bonding structure.

### CROSS REFERENCE TO RELATED APPLICATION

The present application claims priority under 35 U.S.C. §119(a) to Korean Patent Application No. 10-2025-0046024 filed in the Korean Intellectual Property Office on Apr. 9, 2025, which application is incorporated herein by reference in its entirety.

### BACKGROUND

### 1. Technical Field

The present disclosure relates to an electronic device and a method of manufacturing the electronic device, including but not limited to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a first structure, a first bonding structure positioned on the first structure, and including a first bonding via having a first central axis and a first bonding pad having a second central axis aligned with the first central axis, a second bonding structure positioned on the first bonding structure, and including a second bonding via having a third central axis misaligned with the first central axis and a second bonding pad having a fourth central axis aligned with the first central axis, and a second structure positioned on the second bonding structure.

According to an embodiment of the present disclosure, a method of manufacturing a semiconductor device may include forming a peripheral circuit wafer including a first real bonding via having a first central axis and a first real bonding pad formed on the first real bonding via and having a second central axis aligned with the first central axis, forming a cell wafer including a second real bonding via having a third central axis and a second real bonding pad positioned on the second real bonding via and having a fourth central axis misaligned with the third central axis, and bonding the peripheral circuit wafer to the cell wafer such that the first real bonding pad faces the second real bonding pad.

According to an embodiment of the present disclosure, a method of manufacturing a semiconductor device may include forming a first test bonding pad, forming a second test bonding pad, bonding the first test bonding pad to the second test bonding pad, calculating a first alignment vector value of the second test bonding pad with respect to the first test bonding pad, calculating a second alignment vector value by converting the first alignment vector value, calculating a third alignment vector value by correcting the second alignment vector value, and forming a second real bonding pad by applying the third alignment vector value.

### BRIEF DESCRIPTION OF THE DRAWINGS

FIG. 1 illustrates a semiconductor device according to an embodiment of the present disclosure.

FIG. 2 illustrates a semiconductor device according to an embodiment of the present disclosure.

FIGS. 3A, 3B, and 4A-4H are cross sections of a semiconductor device formed utilizing a method of manufacturing a semiconductor device according to an embodiment of the present disclosure.

FIGS. 5A, 5B, 6A, 6B, 7A and 7B are cross sections of a semiconductor device formed utilizing a method of manufacturing a semiconductor device according to an embodiment of the present disclosure.

FIG. 8 illustrates a semiconductor device according to an embodiment of the present disclosure.

### DETAILED DESCRIPTION

The present disclosure describes a semiconductor device having a stable structure and an improved characteristic, and a method of manufacturing the semiconductor device.

According to the present disclosure, a semiconductor device having a stable structure and improved reliability may be described.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “above,” “overlap,” “on,” “upper,” “lower,” “high,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

When one component is identified as “connected” to another component, the components may be connected directly or through at least one intervening component between the components. When two components are identified as “directly connected,” one component is directly connected to the other component without an intervening component between the two components.

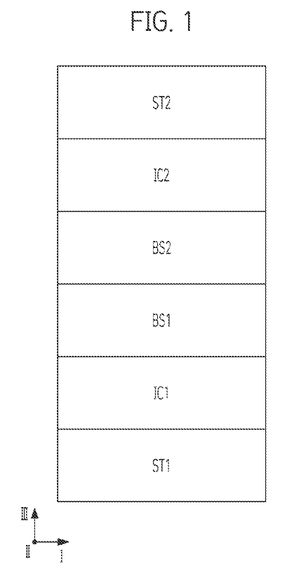

FIG. 1 illustrates a semiconductor device according to an embodiment of the present disclosure.

Referring to FIG. 1, the semiconductor device includes a first structure ST1, a second structure ST1, a first interconnection structure IC1, a second interconnection structure IC2, a first bonding structure BS1, and a second bonding structure BS2. For example, the semiconductor device has a form in which the first structure ST1, the first interconnection structure IC1, the first bonding structure BS1, the second bonding structure BS2, the second interconnection structure IC2, and the second structure ST2 are stacked. A stack direction includes a third direction III crossing first direction I and a second direction II.

The first structure ST1 may include a peripheral circuit. For example, the first structure ST1 may include a transistor and so forth.

The first interconnection structure IC1 is positioned on the first structure ST1 and is connected to the first structure ST1. The first interconnection structure IC1 includes first connection vias and first connection lines. At least one of the first connection vias is connected to the first structure ST1. The first connection lines interconnect the first connection vias.

The first bonding structure BS1 is positioned on the first interconnection structure IC, and is connected to the first interconnection structure IC1. The first bonding structure BS1 includes first bonding vias and first bonding pads. The first bonding vias are connected to the first connection lines. The first bonding pads are connected to the first bonding vias.

The first bonding via has a first central axis. The first bonding pad has a second central axis. The first central axis and the second central axis may be aligned in one example. The first central axis and the second central axis may be misaligned in another example. Misalignment between central axes includes that the central axes are spaced apart and not aligned in a first direction I, a second direction II, or the first direction I and the second direction II.

The second bonding structure BS2 is positioned on the first bonding structure BS1 and is connected to the first bonding structure BS1. The second bonding structure BS2 includes second bonding vias and second bonding pads. The second bonding pads are connected to the first bonding pads. The second bonding vias are connected to the second bonding pads.

The second bonding via has a third central axis. The second bonding pad has a fourth central axis. The third central axis may be misaligned with the first central axis. The fourth central axis may be misaligned with the third central axis and may be aligned with the first central axis. The second bonding pad may be aligned with the first bonding pad and may be misaligned with the second bonding via.

The second interconnection structure IC2 is positioned on the second bonding structure BS2 and is connected to the second bonding structure BS2. The second interconnection structure IC2 is connected to the second structure ST2. The second interconnection structure IC2 includes second connection vias and second connection lines. The second connection lines are connected to the second bonding vias, and the second connection vias are connected to the second connection lines.

The second structure ST2 is positioned on the second interconnection IC2. The second structure ST2 may include stacked memory cells. The second structure ST2 may include a gate structure and through structures extending through the gate structure. The gate structure may include stacked conductive lines. The conductive lines may include a word line, a bit line, a selection line, and the like. The through structures may include channel structures, electrode structures, and the like. Memory cells may be located in areas where the through structures and the conductive lines cross.

In an example, the first structure ST1 is a peripheral circuit and the second structure ST2 is a memory cell array, although components included in the structures ST1 and ST2 are not limited to this example. For example, the first structure ST1 may be a memory cell array and the second structure ST2 may include a peripheral circuit. Alternatively, the structures ST1 and ST2 may each be memory cell arrays.

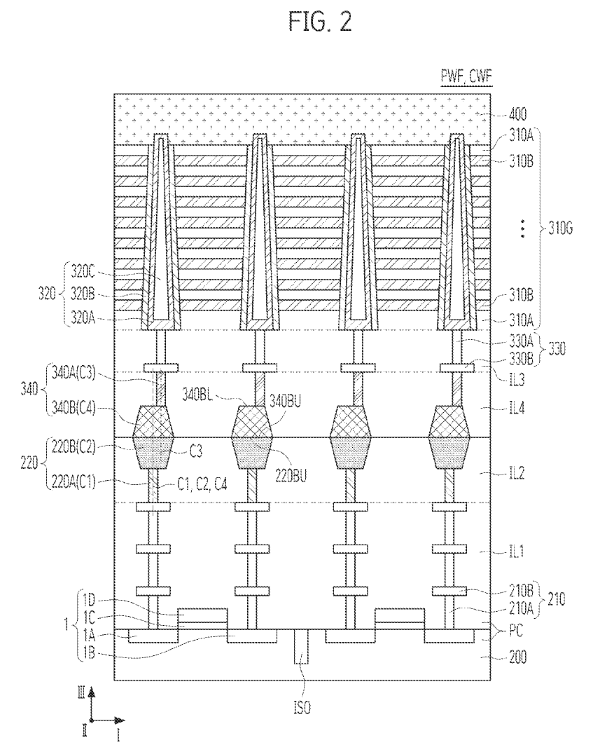

FIG. 2 illustrates a semiconductor device according to an embodiment of the present disclosure.

Referring to FIG. 2, the semiconductor device includes a peripheral circuit PC, a first interconnection structure 210, a first bonding structure 220, a second bonding structure 340, a second interconnection structure 330, a gate structure 310G, and channel structures 320. The semiconductor device includes a substrate 200, a source structure 400, a first interlayer insulating layer IL1, a second interlayer insulating layer IL2, a third interlayer insulating layer IL3, and a fourth interlayer insulating layer IL4.

The peripheral circuit PC is disposed on the substrate 200. In an embodiment, the peripheral circuit PC is included in the first structure ST1 of FIG. 1. The peripheral circuit PC includes a transistor 1 and the like. The transistor 1 includes junctions 1A and 1B, a gate electrode 1D, and a gate insulating layer 1C. The gate insulating layer 1C is located between the gate electrode 1D and the substrate 200. An element isolation layer ISO is located within the substrate 200, an active region is bordered by the element isolation layer ISO, and the transistor 1 is located in the active region.

The first interconnection structure 210 is positioned on the peripheral circuit PC. The first interconnection structure 210 includes first connection vias 210A and first connection lines 210B. The first interconnection structure 210 is located within in the first interlayer insulating layer IL1. The first interlayer insulating layer IL1 is positioned on the substrate 200. One of the first connection vias 210A is connected to the peripheral circuit PC. The first connection lines 210B are connected to the first connection vias 210A, and one of the first connection lines 210B is connected to the first bonding structure 220. The first interconnection structure 210 may include a conductive material such as tungsten, and the first interlayer insulating layer IL1 may include an insulating material such as an oxide or a nitride.

The first bonding structure 220 is positioned on the first interconnection structure 210. The first bonding structure 220 is located within the second interlayer insulating layer IL2. The second interlayer insulating layer IL2 is positioned on the first interlayer insulating layer IL1. The first bonding structure 220 is connected to the first interconnection structure 210. The first interconnection structure 210 is located between the peripheral circuit PC and the first bonding structure 220 and connects the peripheral circuit PC and the first bonding structure 220. The second interlayer insulating layer IL2 may include an insulating material such as an oxide or a nitride, and the first bonding structure 220 may include a conductive material such as tungsten or copper.

The first bonding structure 220 includes first bonding vias 220A and first bonding pads 220B. The first bonding pads 220B are positioned on the first bonding vias 220A. Each of the first bonding vias 220A is connected to one of the first connection lines 210B. The first bonding pads 220B are connected to the first bonding vias 220A, for example, on a 1:1 basis. The first bonding via 220A has a first central axis C1. The first bonding pad 220B has a second central axis C2. The first central axis C1 and the second central axis C2 are aligned in this example.

The second bonding structure 340 is positioned on the first bonding structure 220. The second bonding structure 340 is connected to the first bonding structure 220. The second bonding structure 340 is positioned in the fourth interlayer insulating layer IL4. The fourth interlayer insulating layer IL4 is positioned on the second interlayer insulating layer IL2. The fourth interlayer insulating layer IL4 includes an insulating material such as an oxide or a nitride, and the second bonding structure 340 includes a conductive material such as tungsten or copper.

The second bonding structure 340 includes second bonding vias 340A and second bonding pads 340B. The second bonding vias 340A are positioned on the second bonding pads 340B. The second bonding pads 340B are connected to the first bonding pads 220B. For example, the first bonding pad 220B are bonded to the second bonding pads 340B such that an upper surface 220BU of the first bonding pad 220B faces an upper surface 340BU of the second bonding pad 340B. An upper portion and a lower portion may be used interchangeably for convenience of description. For example, considering a process for manufacturing the semiconductor device, the second bonding pad 340B is formed on the second bonding via 340A. Because the second bonding pad 340B is rotated to bond the second bonding pad 340B to the first bonding pad 220B, the second bonding pad 340B is be positioned on the first bonding pad 220B.

The second bonding via 340A has a third central axis C3. The second bonding pad 340B has a fourth central axis C4. The third central axis C3 is misaligned with the fourth central axis C4. During a process of manufacturing the semiconductor device, a layout of a mask pattern used to form the second bonding pad 340B may be corrected, adjusted, or calibrated. Because the second bonding pad 340B is formed as a pad and a process margin exists on a lower surface 340BL of the second bonding pad 340B, correction, adjustment, or calibration of a layout of a mask pattern used to form the second bonding via 340A is not performed. Therefore, the second bonding via 340A and the second bonding pad 340B are formed in a misaligned state.

The third central axis C3 is misaligned with at least one of the first central axis C1, the second central axis C2, or the fourth central axis C4. The first bonding via 220A, the first bonding pad 220B, and the second bonding pad 340B are aligned, and the second bonding via 340A is misaligned with the first bonding via 220A, the first bonding pad 220B, and the second bonding pad 340B.

When the first bonding pad and the second bonding pad are misaligned, a defect in electrical connection may occur. For example, current may not properly flow between the first bonding pad and the second bonding pad. Due to a bonding defect, a high resistance may result in a bonded wafer, and data stored in a memory cell may be damaged or may not be properly read. When the first bonding pad and the second bonding pad are misaligned, area of a bonding interface is smaller than when the first bonding pad and the second bonding pad are aligned and bonded, and delamination may occur.

According to an embodiment of the present disclosure, the first bonding pad 220B and the second bonding pad 340B are aligned. Effects resulting from a defect that occurs in the electrical connection between the first bonding pad 220B and the second bonding pad 340B may be prevented or reduced. According to an embodiment of the present disclosure, because an area of a bonding interface between the first bonding pad 220B and the second bonding pad 340B is sufficient or meets a target value, occurrence of delamination may be prevented or reduced at the bonding interface.

Although not shown in FIG. 2, the bonding structures 220 and 340 may include barrier layers. For example, barrier layers surrounding the bonding vias 220A and 340A and barrier layers surrounding the bonding pads 220B and 340B may be included.

The second interconnection structure 330 is positioned on the second bonding structure 340 and is connected to the second bonding structure 340. The second interconnection structure 330 is located within the 3rd interlayer insulating layer IL3. The fourth interlayer insulating layer IL4 is positioned on the third interlayer insulating layer IL3. The second interconnection structure 330 includes second connection vias 330A and second connection lines 330B. One of the second connection lines 330B is connected to the second bonding via 340A. The second connection lines 330B are connected to the second connection vias 330A. The third interlayer insulating layer IL3 includes an insulating material such as an oxide, and the second interconnection structure 330 includes a conductive material such as tungsten.

The gate structure 310G is positioned on the second interconnection structure IC2. The gate structure 310G includes insulating layers 310A alternately stacked with conductive layers 310B. The conductive layers 310B may include a word line, a bit line, a selection line, and the like as a gate line.

The channel structures 320 extend into the source structure 400 through the gate structure 310G. The source structure 400 is positioned on the gate structure 310G. Each of the channel structures 320 includes a channel layer 320A and a memory layer 320B surrounding the channel layer 320A. Each of the channel structures 320 further includes an insulating core 320C in the channel layer 320A. The channel layer 320A is connected to the source structure 400.

The channel structures 320 are connected to the second bonding structure 340 through the second interconnection structure 330. The second interconnection structure 330 is positioned between the gate structure 310G and the second bonding structure 340 and connects the channel structures 320 and the second bonding structure 340. For example, the second connection vias 330A are connected to the channel structures 320. The second connection lines 330B may be used as a bit line or a gate line.

For example, the first central axis C1, the second central axis C2, and the fourth central axis C4 are aligned, and the third central axis C3 is misaligned with the central axes C1, C2, and C4 as shown in FIG. 2, although the present disclosure is not limited to this example. For example, the first central axis C1 and the second central axis C2 may be misaligned, and the second central axis C2, the third central axis C3, and the fourth central axis C4 may be aligned. Alternatively, the first central axis C1 and the second central axis C2 may be misaligned, the third central axis C3 and the fourth central axis C4 may be misaligned, and the second central axis C2 and the fourth central axis C4 may be aligned. Alternatively, the first, second, third, and fourth central axes C1, C2, C3, and C4 may be aligned.

According to the described structure, the second central axis C2 of the first bonding pad 220B and the fourth central axis C4 of the second bonding pad 340B may be aligned. In this example, problems resulting from a bonding defect between the first bonding pad 220B and the second bonding pad 340B may be avoided, prevented, or reduced. The fourth central axis C4 of the second bonding pad 340B and the third central axis C3 of the second bonding via 340A may be misaligned. This misalignment occurs because the layout of the mask pattern used to form the second bonding pad 340B is corrected during the process of manufacturing the semiconductor device.

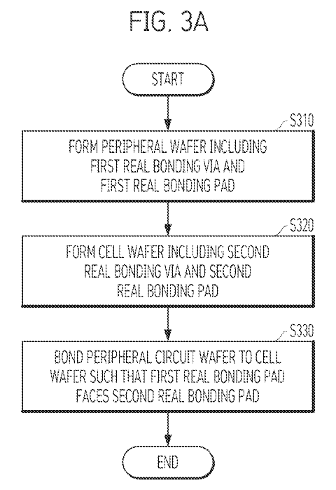

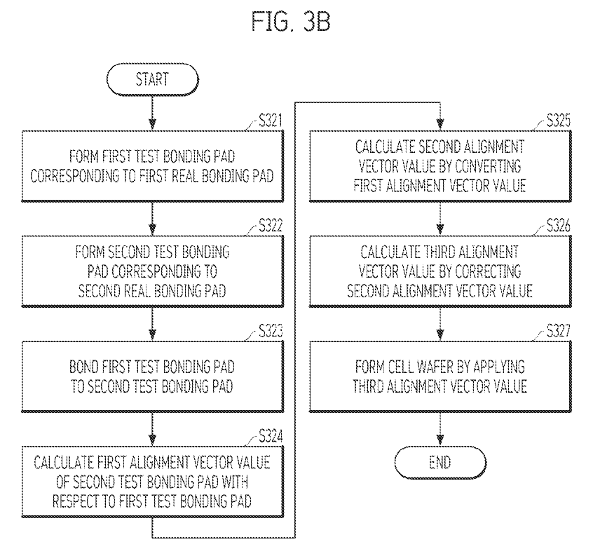

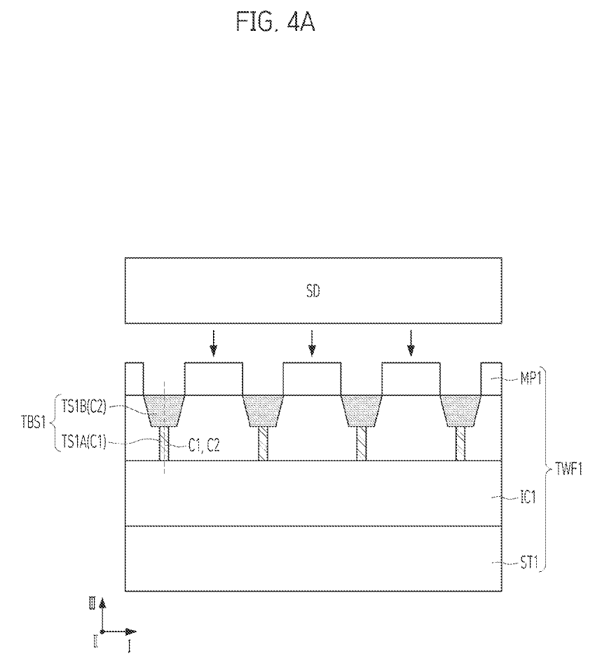

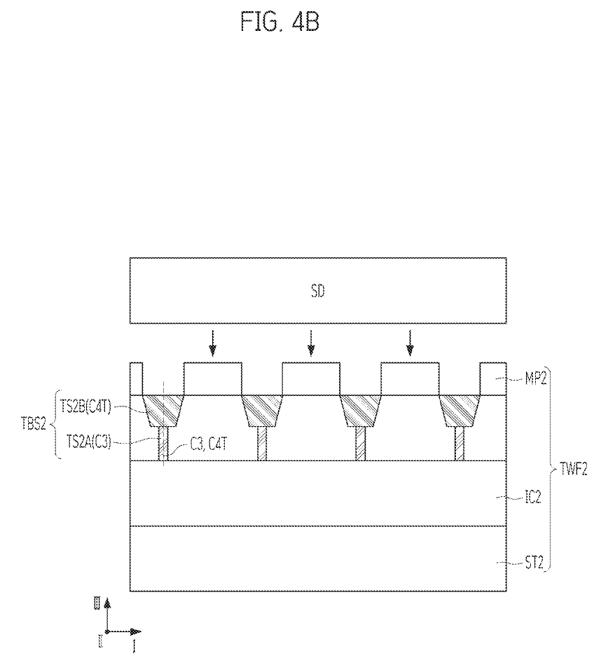

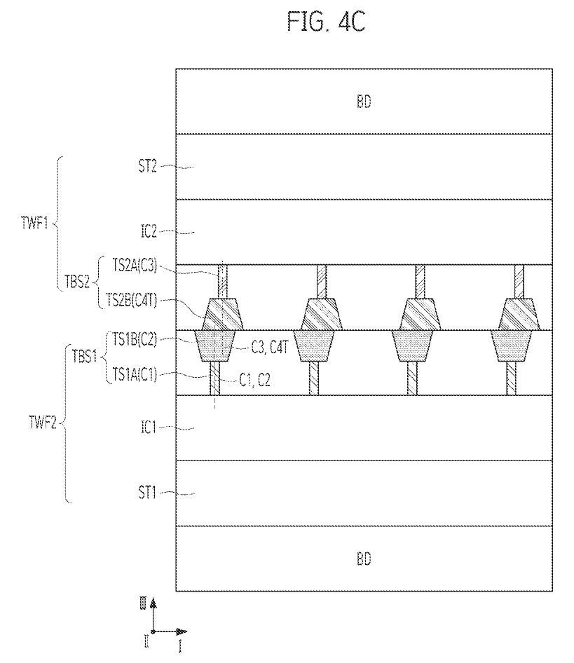

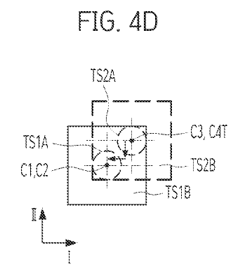

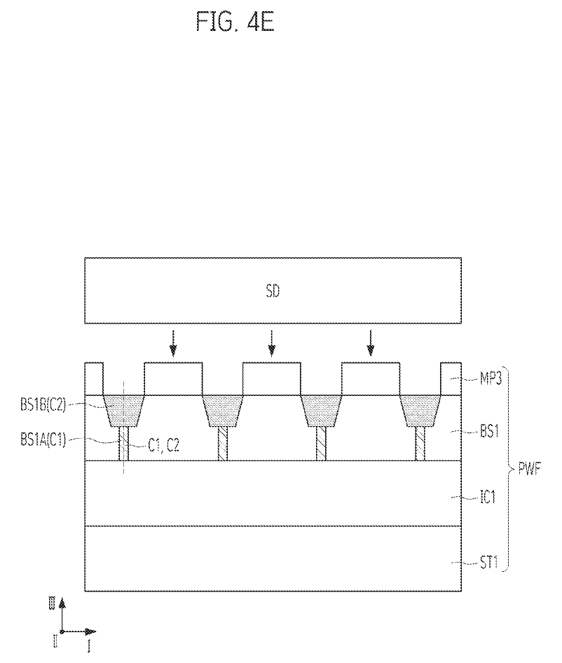

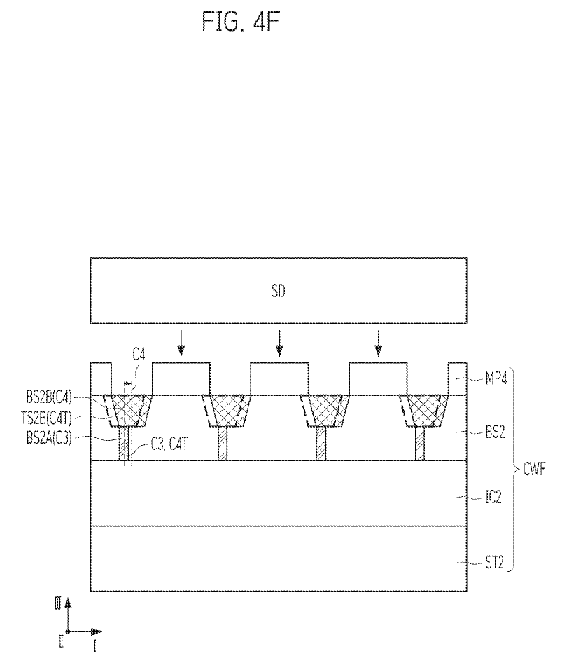

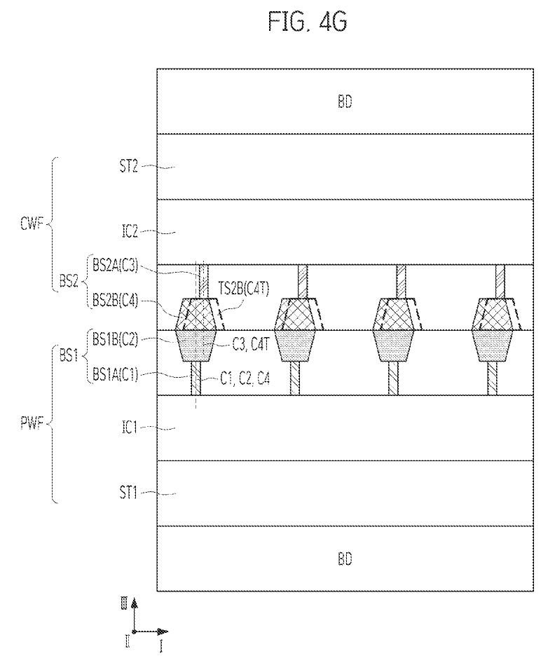

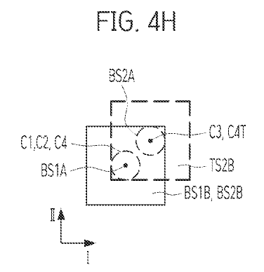

FIGS. 3A, 3B, and 4A-4H are cross sections of a semiconductor device formed utilizing a method of manufacturing a semiconductor device according to an embodiment of the present disclosure. FIGS. 3A and 4E-4H are cross sections of a semiconductor device formed utilizing a method of forming a cell wafer based on correction data, and FIGS. 3B and 4A-4D are cross sections of a semiconductor device formed utilizing a method of obtaining the correction data.

Referring to FIGS. 3A and 4E, a peripheral circuit wafer PWF including a first real bonding via BS1A and a first real bonding pad BS1B is formed S310. The first real bonding via BS1A has a first central axis C1, and the first real bonding pad BS1B has a second central axis C2. The first central axis C1 and the second central axis C2 are aligned.

The term "real" refers to a structure or value that is actually applied or implemented in the semiconductor device during manufacturing or operation, whereas the term "test" denotes a structure or value that is used for simulation, verification, or comparative analysis but is not physically implemented in the final semiconductor device. Accordingly, a “real bonding pad” is one that exists in the actual layout or functional operation of the semiconductor device, while a “test bonding pad” represents a theoretical or intermediate reference used for design evaluation purposes.

Layout information and correction data for patterning components of the peripheral circuit wafer PWF may be stored in a scanner device SD. Layout information corrected such that a mask pattern transferred to the wafer has a target shape and alignment are formed by applying the correction data to the layout information. Therefore, components are formed on the wafer by transferring the mask pattern that reflects the corrected layout information on the mask pattern. The correction data includes data related to an alignment error, deformation, or the like that may occur during a bonding process. The bonding data may be obtained through a process of bonding test wafers.

For example, the first real bonding pad BS1B is formed using the scanner device SD. By reflecting the corrected layout information in a third mask pattern MP3 and transferring the third mask pattern MP3 to the peripheral circuit wafer PWF, a trench is formed in the peripheral circuit wafer PWF, and the first real bonding pad BS1B is formed in the trench.

The peripheral circuit wafer PWF includes a first structure ST1 and a first interconnection structure IC1. The first structure ST1 may be formed before forming the first real bonding via BS1A and the first real bonding pad BS1B in this example. The first structure ST1 includes a peripheral circuit. The first interconnection structure IC1 is formed on the first structure ST1. The first structure ST1 and the first real bonding via BS1A and/or the first real bonding pad BS1B are connected through the first interconnection structure IC1.

Referring to FIGS. 3A and 4F, a cell wafer CWF including a second real bonding via BS2A and a second real bonding pad BS2B is formed S320. The second real bonding via BS2A has a third central axis C3, and the second real bonding pad BS2B has a fourth central axis C4. The third central axis C3 is misaligned with the fourth central axis C4 for various reasons, such as a process issue.

The second real bonding pad BS2B is formed using the scanner device SD. By reflecting the corrected layout information in a fourth mask pattern MP4 and transferring the fourth mask pattern MP4 to the cell wafer CWF, a trench is formed in the cell wafer CWF, and the second real bonding pad BS2B is formed in the trench. In this example, the second real bonding pad BS2B is formed misaligned with the second real bonding via BS2A according to the corrected layout information.

The cell wafer CWF includes a second structure ST2 and a second interconnection structure IC2. The second structure ST2 is formed before forming the second real bonding via BS2A and the second real bonding pad BS2B in this example. The second structure ST2 may include stacked memory cells. The second structure ST2 may include a gate structure and through structures extending through the gate structure. The gate structure may include stacked conductive lines. The conductive lines may include a word line, a bit line, a selection line, and the like. The through structures may include channel structures, electrode structures, and the like. Memory cells are positioned where the through structures and the conductive lines intersect or cross. The second interconnection structure IC2 is formed on the second structure ST2. The second structure ST2 and the second real bonding via BS2A and/or the second real bonding pad BS2B are connected through the second interconnection structure IC2.

Referring to FIGS. 3A, 4G, and 4H, the peripheral circuit wafer PWF is bonded S330 to the cell wafer CWF such that the first real bonding pad BS1B faces the second real bonding pad BS2B. For example, the peripheral circuit wafer PWF and the cell wafer CWF may be bonded using a bonding device BD. The fourth central axis C4 is aligned with the first central axis C1 and the second central axis C2, and the third central axis C3 is misaligned with the first central axis C1, second central axis C2, and the fourth central axis C4. The second central axis C2 of the first real bonding pad BS1B and the fourth central axis C4 of the second real bonding pad BS2B are aligned.

Referring to FIGS. 3B, 4A and 4E, a first test bonding pad TS1B corresponding to the first real bonding pad BS1B is formed S321. A first test wafer TWF1 including a first test bonding via TS1A and the first test bonding pad TS1B corresponding to the first real bonding via BS1A is formed. The first test bonding via TS1A has a central axis substantially the same as the first central axis C1 of the first real bonding via BS1A, and the first test bonding pad TS1B has a central axis substantially the same as the second central axis C2 of the first real bonding pad BS1B. Therefore, the first test bonding via TS1A and the second test bonding via TS1B are aligned.

The first test bonding pad TS1B is formed using the scanner device SD. By reflecting the layout information before correction in a first mask pattern MP1 and transferring the first mask pattern MP1 to the first test wafer TWF1, a trench is formed in the first test wafer TWF1, and the first test bonding pad TS1B is formed in the trench. The first mask pattern MP1 is substantially the same as the third mask pattern MP3.

Referring to FIGS. 3B, 4B, and 4F, a second test bonding pad TS2B corresponding to the second real bonding pad BS2B is formed S322. A second test wafer TWF2 including a second test bonding via TS2B and the second test bonding pad TS2B corresponding to the second real bonding via BS2A is formed. The second test bonding via TS2A has a central axis substantially the same as the third central axis C3 of the second real bonding via BS2A, and the second test bonding pad TS2B has a fifth central axis C4T different from the fourth central axis C4 of the second real bonding pad BS2B. The second test bonding via TS2A and the second test bonding pad TS2B are aligned. The third central axis C3 and the fifth central axis C4T are aligned.

The second test bonding pad TS2B is formed using the scanner device SD. By reflecting the layout information before correction in a second mask pattern MP2 and transferring the second mask pattern MP2 to the second test wafer TWF2, a trench is formed in the second test wafer TWF2, and the second test bonding pad TS2B is formed in the trench. The second mask pattern MP2 may be substantially the same as the fourth mask pattern MP4.

Referring to FIGS. 3B, 4C, and 4D, the first test bonding pad TS1B is bonded S323 to the second test bonding pad TS2B. The first test wafer TWF1 and the second test wafer TWF2 are bonded using the bonding device BD such that an upper surface of the first test bonding pad TS1B faces an upper surface of the second test bonding pad TS2B. The second test bonding pad TS2B is positioned on the first test bonding pad TS1B. The first test bonding pad TS1B and the second test bonding pad TS2B are misaligned. The second central axis C2 and the fifth central axis C4T are misaligned.

A first alignment vector value relating the second test bonding pad TS2B to the first test bonding pad TS1B is calculated S324. For example, the first alignment vector value is calculated with respect to how much the fifth central axis C4T of the second test bonding pad TS2B deviates in a first direction I, a second direction II crossing the first direction I, and/or the first direction I and the second direction II with respect to the second central axis C2 of the first test bonding pad TS1B.

A second alignment vector value is calculated by converting S325 the first alignment vector value. For example, because the first test bonding pad TS1B is bonded to the second test bonding pad TS2B such that the upper surface of the first test bonding pad TS1B faces the upper surface of the second test bonding pad TS2B, and the second test bonding pad TS2B is positioned on the first test bonding pad TS1B, the first alignment vector value is inverted with respect to the first direction I and the second direction II. Therefore, the second alignment vector value is calculated by inverting or converting the first alignment vector value with respect to the first direction I and the second direction II.

When bonding the first test bonding pad TS1B and the second test bonding pad TS2B, when the first test bonding pad TS1B is positioned on the second test bonding pad TS2B, this conversion process is not performed.

A third alignment vector value is calculated by correcting S326 the second alignment vector value. A residual second alignment vector value is calculated by removing first elements from the second alignment vector value. A second layout is formed by applying the residual second alignment vector value to a first layout of the second mask pattern MP2 used to form the second test bonding pad TS2B. The third alignment vector value is calculated by removing nth elements from the second layout, where n is an integer greater than 1.

The nth elements includes first elements (linear terms) and high order elements (high order terms). The first elements (linear terms) include an alignment error, deformation, and the like applied at the same rate to the entire wafer, which errors may occur using the bonding device BD. The high order elements (high order terms) include deformation that occur differently depending on a position in a wafer. For example, the alignment error or deformation may be severe in a first region, and the alignment error or deformation may not be severe in a second or different region.

The first elements include at least one of a translation vector value in the first direction I Translation X, a translation vector value in the second direction II Translation Y, an expansion vector value in the first direction I Expansion X, an expansion vector value in the second direction II Expansion Y, a one-dimensional rotation vector value Rotation, and a non-orthogonality vector value Non-orthogonality.

The translation vector value in the first direction I and the second direction II Translation X, Y includes a vector value indicating how much the second test wafer TWF2 deviates in the first direction I and/or the second direction II with respect to the first test wafer TWF1. The expansion vector value in the first direction I and the second direction II Expansion X, Y includes a vector value indicating how much the second test wafer TWF2 expands in the first direction I and/or the second direction II with respect to the first test wafer TWF1. The one-dimensional rotation vector value includes a vector value indicating how much the second test wafer TWF2 rotates with respect to the first test wafer TWF1. The non-orthogonality vector value includes a vector value indicating that the first direction I or X axis is not orthogonal with the second direction II or Y-axis or the first direction I is at an angler other than 90 degrees with respect to the second direction II.

The high order elements include at least one of a real rotation vector value Real Rotation, a measurement rotation vector value Apparent Rotation, a real magnification vector value Real Magnification, and a measurement magnification vector value Apparent Magnification.

The real rotation vector value includes a vector value representing actual rotation of the second test wafer TWF2 with respect to the first test wafer TWF1. The measurement rotation vector value includes a vector value including the real rotation vector value as well as other geometric elements, such as deformation, alignment error, distortion, and the like. The real magnification vector value includes a vector value of a percentage by which the second test wafer TWF2 is expanded or reduced during a bonding process. The measurement magnification vector value includes a vector value including the real magnification vector value as well as other geometric elements such as scanner distortion, measurement error, and the like.

As described, the first elements include the alignment error, the deformation, and the like applied at the same rate to the entire wafer in an embodiment. When the first elements that occur due to the bonding device are not removed from the second alignment vector value, correction may not proceed normally with respect to wafers except for a sample wafer among slots included in a lot. Thus, a correction value calculated based on the sample wafer may not compensate normally in the subsequently manufactured wafers. According to an embodiment of the present disclosure, this problem may be reduced because the residual second alignment vector value is used to remove the first elements from the second alignment vector value. According to an embodiment of the present disclosure, by removing an error that caused by the bonding device BD from the entire wafer, an overlay characteristic of the entire wafer remains.

The second layout is formed by applying the residual second alignment vector value to the first layout of the second mask pattern MP2 used to form the second test bonding pad TS2B. In this example, when performing correction on the nth elements in the scanner device SD, the second layout is recognized as actual data and correction may be performed. The term "actual data" refers to data that is interpreted by the scanner device SD as a finalized layout to be used for correction or exposure. Therefore, the second layout is treated as actual data when it is recognized as an input for performing physical correction in the scanner device SD.

The third alignment vector value is calculated by removing the nth elements from the second layout. For example, the third alignment vector value is calculated by performing correction that removes the nth elements from the second layout in the scanner device SD. The third alignment vector value is calculated by performing correction that removes the nth elements on each of the wafers included in the lot in the scanner device SD. According to an embodiment of the present disclosure, a more precise third alignment vector value may be obtained for each of the wafers by performing correction for high-order elements as well as correction for the first order elements related to the bonding device BD.

The corrected layout is formed by applying S327 the third alignment vector value to the layout of the fourth mask pattern MP4 used to form the second real bonding pad BS2B. In this example, by reflecting the corrected layout, the second real bonding pad BS2B is formed. For example, by reflecting the corrected layout to the fourth mask pattern MP4 and transferring the fourth mask pattern MP4 to the cell wafer CWF, the second real bonding pad BS2B is formed.

The second real bonding via BS2A and the second real bonding pad BS2B of the cell wafer CWF are misaligned as shown, although the present disclosure is not limited to this example. For example, the first real bonding via BS1A and the first real bonding pad BS1B of the peripheral circuit wafer CWF may be misaligned, and the first real bonding pad BS1B and the second real bonding pad BS2B may be aligned.

According to the described manufacturing method, correction data for an alignment error, deformation, and the like occurring during a process of bonding the first test bonding pad TS1B and the second test bonding pad TS2B may be obtained during a process of bonding the first test wafer TWF1 to the second test wafer TWF2. Using this correction data, the first real bonding pad BS1B of the peripheral circuit wafer PWF and the second real bonding pad BS2B of the cell wafer CWF may be formed as aligned by correcting the existing layout in the scanner device SD.

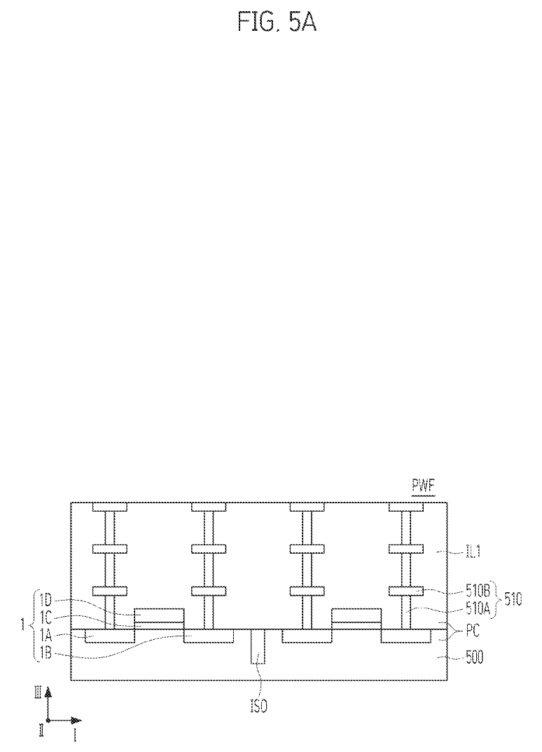

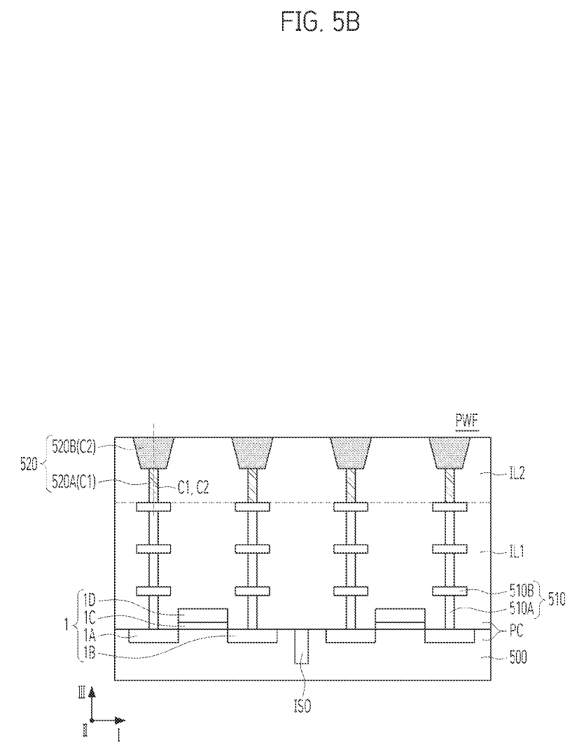

FIGS. 5A, 5B, 6A, 6B, 7A, and 7B are cross sections of a semiconductor device formed utilizing a method of manufacturing a semiconductor device according to an embodiment of the present disclosure.

Referring to FIG. 5A, a peripheral circuit PC is formed on a first substrate 500. The peripheral circuit PC includes a transistor 1 and the like. The transistor 1 includes junctions 1A and1B, a gate insulating layer 1C, and a gate electrode 1D.

A first interconnection structure 510 may be formed on the peripheral circuit PC. The first interconnection structure 510 is formed in a first interlayer insulating layer IL1. The first interlayer insulating layer IL1 is formed on the first substrate 500. The first interconnection structure IC1 includes first connection vias 510A and first connection lines 510B. At least one of the first connection vias 510A is connected to the peripheral circuit PC. The first connection lines 510B interconnect the first connection vias 510A.

Referring to FIG. 5B, a first bonding structure 520 is formed on the first interconnection structure 510. The first bonding structure 520 is formed in a second interlayer insulating layer IL2. The second interlayer insulating layer IL2 is formed on the first interlayer insulating layer IL1. The first bonding structure 520 includes first bonding vias 520A having a first central axis C1 and first bonding pads 520B having a second central axis C2. The first central axis C1 and the second central axis C2 are aligned.

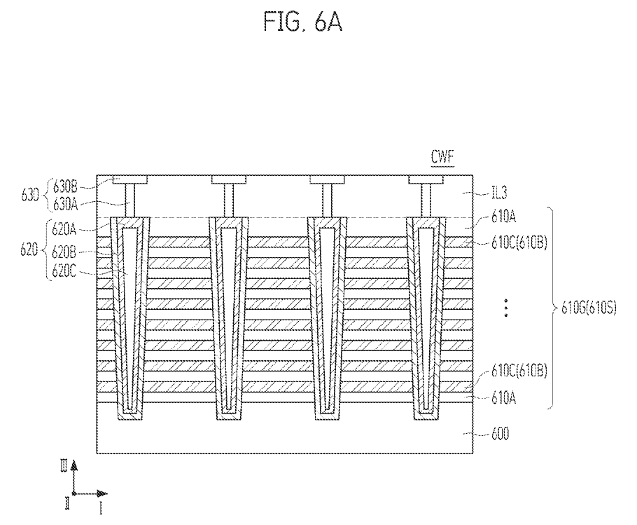

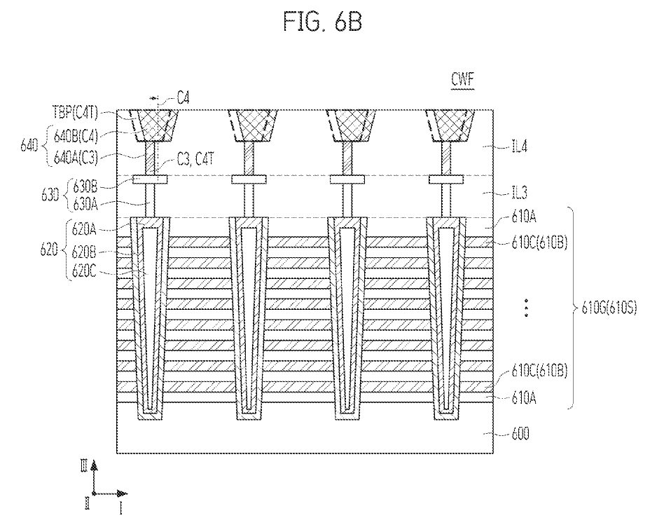

Referring to FIG. 6A, a stack 610S is formed on a second substrate 600. For example, the stack 610S is formed by alternately stacking first material layers 610A with second material layers 610B. The first material layers 610A include an insulating material such as an oxide, and the second material layers 610B include a sacrificial material such as a nitride.

Channel structures 620 extending into the second substrate 600 through the stack 610S are formed. Each of the channel structures 620 includes a channel layer 620A, a memory layer 620B surrounding the channel layer 620A, and an insulating core 620C within the channel layer 620A.

The second material layers 610B are replaced with third material layers 610C through a slit (not shown) extending through the stack 610S. Accordingly, a gate structure 610G in which the first material layers 610A alternately stacked with the third material layers 610C are formed. The third material layers 610C may include a word line, a bit line, a selection line, or the like as a gate line. The third material layers 610C include a conductive material such as tungsten. When the second material layers 610B include a conductive material, a process of replacing the second material layers 610B with the third material layers 610C is not performed. In this example, the stack 610S may be used as the gate structure 610G.

A second interconnection structure 630 is formed on the gate structure 610G. The second interconnection structure 630 is formed in a third interlayer insulating layer IL3. The third interlayer insulating layer IL3 is formed on the gate structure 610G. The second interconnection structure 630 includes second connection vias 630A and second connection lines 630B. The second connection vias 630A are connected to the channel structures 620. The second connection lines 630B are connected to the second connection vias 630A. The second connection lines 630B may be used as a bit line or a gate line. The second interconnection structure 630 includes a conductive material such as tungsten.

Referring to FIG. 6B, a second bonding structure 640 is formed on the second interconnection structure 630. The second bonding structure 640 is formed within a fourth interlayer insulating layer IL4. The fourth interlayer insulating layer IL4 is formed on the third interlayer insulating layer IL3. The second bonding structure 640 includes second bonding vias 640A having a third central axis C3 and second bonding pads 640B having a fourth central axis C4. The third central axis C3 is misaligned with the fourth central axis C4.

When bonding pads are not aligned, a defect in electrical connection may occur, such as current not properly flowing between the bonding pads. Due to a bonding defect, a high resistance may result in a bonded wafer, and data stored in a memory cell may be damaged or may be not properly read. In this example, alignment between test bonding pads of test wafers may be confirmed using a process of bonding the test wafers before forming the peripheral circuit wafer PWF and the cell wafer CWF. When the test bonding pads are misaligned, the first bonding pads 520B may be aligned with the second bonding pads 640B formed using a correction process.

According to an embodiment of the present disclosure, the test bonding pads of the test wafers are misaligned using a process of bonding the test bonding pads. For example, a test bonding pad corresponding to the first bonding pad 520B is misaligned with a test bonding pad TBP corresponding to the second bonding pad 640B having the fifth central axis C4T. In this example, the second bonding pad 640B is formed aligned with the first bonding pad 520B using the correction process as described with reference to FIGS. 3A, 3B, and 4A-4H. The fourth central axis C4 of the second bonding pad 640B is moved from the fifth central axis C4T of the test bonding pad TBP. Because the second bonding pad 640B is formed as a pad and a process margin exists on a lower surface, even when the second bonding pad 640B and the second bonding via 640A are misaligned, the second bonding via 640A and the second bonding pad 640B are connected.

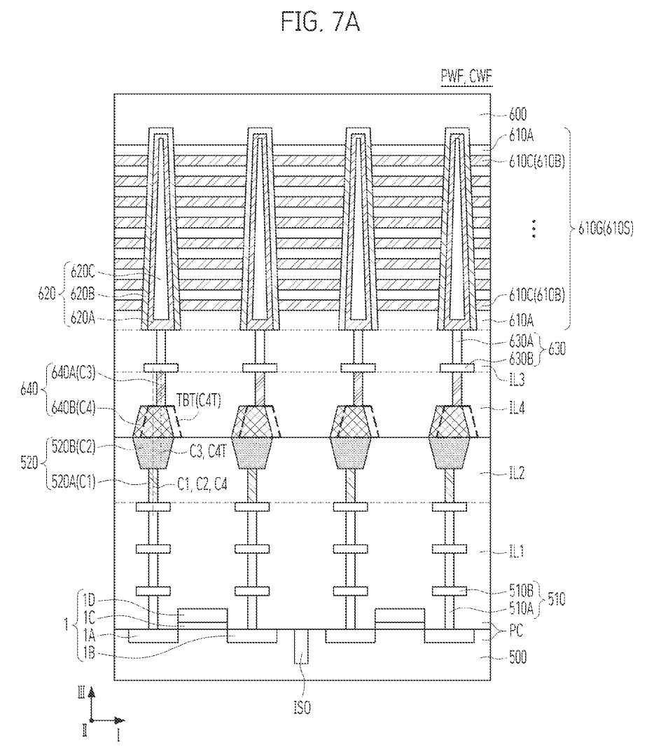

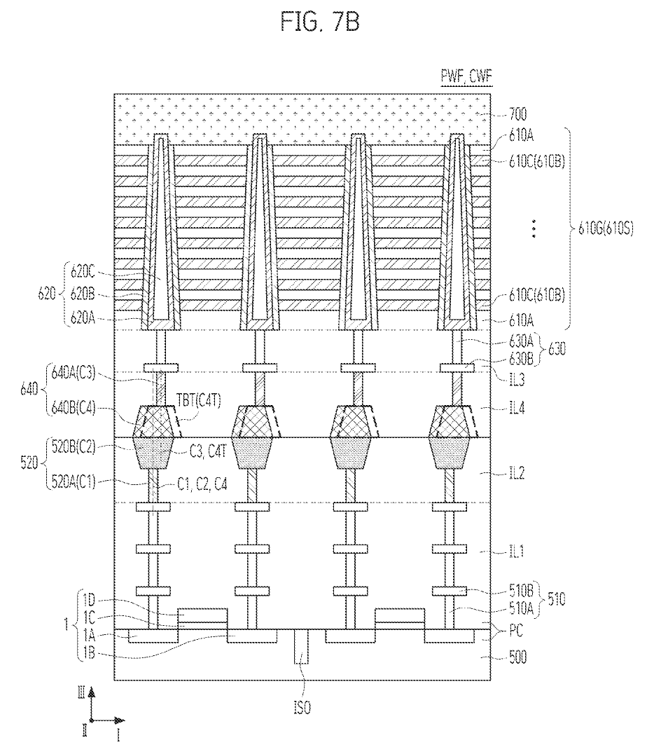

Referring to FIG. 7A, the first bonding structure 520 is bonded to the second bonding structure 640. For example, the first bonding pads 520B are bonded to the second bonding pads 640B on a 1:1 basis. The first bonding pads 520B and the second bonding pads 640B are aligned. Therefore, defects occurring in an electrical connection between the first bonding pad 520B and the second bonding pad 640B may be prevented or reduced.

The peripheral circuit PC and the channel structures 620 are electrically connected through the first interconnection structure 510, the first bonding structure 520, the second bonding structure 640, and the second interconnection structure 630.

Referring to FIG. 7B, the channel structures 620 are exposed by removing the second substrate 600. The channel layer 620A is exposed by partially removing the memory layer 620B of the channel structures 620. A source structure 700 is formed on the channel structures 620. In this example, the channel layer 620A and the source structure 700 are connected.

According to the described manufacturing method, the first bonding pads 520B and the second bonding pads 640B are formed such that the first bonding pads 520B and the second bonding pads 640B that bond the peripheral circuit wafer PWF to the cell wafer CWF are aligned. In this example, defects occurring in an electrical connection between the first bonding pads 520B and the second bonding pads 640B may be prevented or reduced.

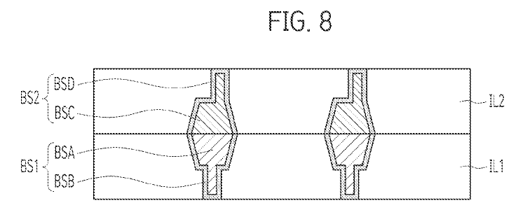

FIG. 8 illustrates a semiconductor device according to an embodiment of the present disclosure.

Referring to FIG. 8, the semiconductor device includes a first interlayer insulating layer IL1, a second interlayer insulating layer IL2, a first bonding structure BS1, and a second bonding structure BS2.

The first bonding structure BS1 is located in the first interlayer insulating layer IL1. The first bonding structure BS1 includes a first bonding section BSA including the first bonding via 220A and the first bonding pad 220B of FIG. 2, and a first barrier layer BSB surrounding the first bonding section BSA. The first barrier layer BSB is located between the first interlayer insulating layer IL1 and the first bonding section BSA.

The second bonding structure BS2 is positioned on the first bonding structure BS1 and is located within the second interlayer insulating layer IL2. The second interlayer insulating layer IL2 is positioned on the first interlayer insulating layer IL1. The second bonding structure BS2 includes a second bonding section BSC including the second bonding via 340A and the second bonding pad 340B of FIG. 2, and a second barrier layer BSD surrounding the second bonding section BSC. The second barrier layer BSD is located between the second interlayer insulating layer IL2 and the second bonding section BSC.

The barrier layers BSB and BSD may prevent or reduce diffusion of a metal material such as copper included in the bonding sections BSA and BSC and are formed between the bonding sections BSA and BSC and the interlayer insulating layers IL1 and IL2, respectively, thereby improving adhesion strength of the first and second bonding sections BSA and BSC. The layers BSB and BSD may include a metal nitride. For example, the first and second barrier layers BSB and BSD may include one of tantalum nitride (TaN), tungsten nitride (WN), or titanium nitride (TiN).

The interlayer insulating layers IL1 and IL2 form a bonding interface during a process of bonding the first bonding structure BS1 to the second bonding structure BS2. The interlayer insulating layers IL1 and IL2 may include a material that improves adhesion strength at the bonding interface. The interlayer insulating layers IL1 and IL2 may include one of an oxide or a nitride. For example, the first and second interlayer insulating layers IL1 and IL2 may include one of silicon oxide (SiO), silicon nitride (SiN), or silicon carbon nitride (SiCN).

The bonding structures BS1 and BS2 may be formed utilizing various different methods. For example, in the bonding structure, a bonding via, and a bonding pad may be integrally formed utilizing a damascene process. For example, in the bonding structure, an upper surface of a bonding via may be exposed through a planarization process after forming the bonding via and a barrier layer surrounding the bonding via, and a bonding pad and a barrier layer surrounding the bonding pad may be separately formed.

According to the described structure, a bonding structure is positioned in an interlayer insulating layer and includes a bonding section and a barrier layer surrounding the bonding section. A bonding interface is formed between the interlayer insulating layers and may include silicon oxide (SiO), silicon nitride (SiN), or silicon carbide nitride (SiCN) to improve adhesion strength at the bonding interface. The barrier layer may prevent copper included in the bonding section from diffusing, and may be positioned between the bonding section and the interlayer insulating layer to improve adhesion strength with the bonding section.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a first structure;
a first bonding structure positioned on the first structure and including a first bonding via having a first central axis and a first bonding pad having a second central axis aligned with the first central axis;
a second bonding structure positioned on the first bonding structure and including a second bonding via having a third central axis misaligned with the first central axis and a second bonding pad having a fourth central axis aligned with the first central axis; and
a second structure positioned on the second bonding structure.

2. The semiconductor device of claim 1, wherein the third central axis is misaligned with at least one of the first central axis, the second central axis, or the fourth central axis.

3. The semiconductor device of claim 2, wherein the third central axis is spaced apart from the first central axis, the second central axis, or the fourth central axis in a first direction, a second direction crossing the first direction, or the first direction and the second direction and is misaligned with the first central axis, the second central axis, or the fourth central axis.

4. The semiconductor device of claim 1, wherein an upper surface of the first bonding pad is bonded to face an upper surface of the second bonding pad.

5. The semiconductor device of claim 1, further comprising:
a first interconnection structure positioned between the first structure and the first bonding structure and connecting the first structure to the first bonding structure; and
a second interconnection structure positioned between the second structure and the second bonding structure and connecting the second structure to the second bonding structure.

6. The semiconductor device of claim 5, wherein the first structure includes a peripheral circuit;
wherein the second structure includes a gate structure and channel structures extending through the gate structure;
wherein the first interconnection structure includes first connection vias and first connection lines; and
wherein the second interconnection structure includes second connection vias and second connection lines.

7. The semiconductor device of claim 6, wherein one of the first connection vias is connected to the peripheral circuit;
wherein each of the first connection lines is connected to a different one of the first connection vias;
wherein the first bonding via is connected to one of the first connection lines; and
wherein the first bonding pad is connected to the first bonding via.

8. The semiconductor device of claim 6, wherein the second connection vias are connected to the channel structures;
wherein each of the second connection lines is connected to a different one of the second connection vias;
wherein the second bonding via is connected to one of the second connection lines; and
wherein the second bonding pad is connected to the second bonding via.

9. The semiconductor device of claim 6, wherein the first bonding via is positioned on the first interconnection structure;
wherein the first bonding pad is positioned on the first bonding via;
wherein the second bonding pad connected to the first bonding pad is positioned on the first bonding pad;
wherein the second bonding via misaligned with the second bonding pad is positioned on the second bonding pad; and
wherein the second interconnection structure is positioned on the second bonding via.

10. The semiconductor device of claim 6, further comprising a source structure positioned on the second structure.

11. The semiconductor device of claim 10, wherein each of the channel structures includes a channel layer and a memory layer surrounding the channel layer, and
the channel layer is connected to the source structure.
